(19) United States
(12) Patent Application Publication
(10) Pub. No.: US 2007/0159791 A1
(43) Pub. Date: Jul. 12, 2007

(54) Low-profile articulated electronics enclosure with improved air coolant system

(75) Inventors: David J. Pongracz, Bangor, PA (US); Rodney M. Sheman, Morristown, NJ (US)

Correspondence Address: MCCORMICK, PAULDING & HUBER LLP, 185 ASYLUM STREET, CITY PLACE II, HARTFORD, CT, 06103, US

(73) Assignee: Lucent Technologies Inc., Murray Hill, NJ (US)

(21) Appl. No.: 11/330,975

(22) Filed: Jan. 11, 2006

(51) Int. Cl. H05K 7/20

(52) U.S. Cl. 361/690; 361/688

(57) ABSTRACT

A system for housing electronic components includes an enclosure with an interior, a door for accessing the interior, and a chassis. The components are attached to the chassis, which is pivotally connected to the enclosure for movement between retracted and deployed positions. In the former, the chassis lies within the interior. In the latter, it lies rotated or swung out the front of the enclosure, allowing for the components to be accessed while minimizing the depth/size of the enclosure. The enclosure includes an air intake in the base of the enclosure, and air exhaust ports in the rear of the enclosure, both protected by baffles/louvers. Air is drawn through the intake (using a fan), up through the interior for cooling purposes, and out the rear of the enclosure through the exhaust ports. This pathway has been found to minimize the ingress of sprayed liquid, for compliance with IEC IP44.

### FIELD OF THE INVENTION

The present invention relates to cabinets or enclosures and, more particularly, to cabinets or enclosures for holding electronic components in a secure manner.

### BACKGROUND OF THE INVENTION

Metal or polymer cabinets or other enclosures are frequently used to house disparate or related electronic components at a point of deployment. For example, the components of a computer terminal (e.g., disk drives and processor boards) may be housed in a case having an outer enclosure, an inner support frame or structure for securely holding the components relative to one another, and one or more doors or hatches for a user to access the interior of the enclosure. Such enclosures are provided to protect the components from external contamination (especially where the components may not be provided with much protection of their own), and to secure the components against tampering and unauthorized removal. Enclosures are also used to space components apart from one another in an orderly and/or pre-determined manner, for thermal management purposes (e.g., for proper air flow between the components) and to facilitate the placement of cables or other electrical interconnects to and from the components.

Many types of enclosures for electronics are not meant to withstand rigorous or varying environmental conditions. For example, while the case for a computer might protect interior components to a limited extent, it is generally recommended that a computer be kept in an environmentally controlled location such as an office, bedroom, or even a dedicated server room. However, certain electronic components have to be placed in locations with less stringent environmental controls, or possibly in locations where environmental conditions are more likely to vary, or where the risk of contamination is greater. For example, the electronics for a cellular network base station, although typically housed in some sort of small building or shed, are necessarily occasionally deployed at locations having a greater exposure to extreme elements, such as hilltops or the like. Also, junction or distribution boxes housing electronic components for controllably distributing telecommunication feeds in a building may have to be installed in a basement, utility room, closet, or similar location, all of which are subject to greater temperature fluctuations and a greater risk of environmental contamination.

Aside from the increased possibility of exposure to environmental contaminants such as dust, debris, and liquids, the placement of enclosures in certain locations may present issues with respect to space limitations and/or thermal management, e.g., cooling. For example, if a junction/distribution box is deployed in a utility or other closet having cramped quarters, it may be difficult to arrange for adequate cooling of the electronics in the distribution box given the space constraints of the closet and/or of the distribution box itself.

### SUMMARY OF THE INVENTION

An embodiment of the present invention relates to an enclosure system for housing electronic components. The system includes an enclosure having an interior, a base, and a rear sidewall. An air coolant pathway extends from an air intake in the base (near the bottom of the enclosure), through the interior, and out an air exhaust in the rear sidewall. In another embodiment, baffles are disposed in the air intake and exhaust for limiting the entry of contaminants.

In another embodiment, the base has a front, a rear, and left and right sides. The air intake is positioned on one of the sides of the base. There may be two air intakes, one on each side of the base. Also, the depth of the enclosure may be substantially less than the width of the enclosure (e.g., no more than one-half the width of the enclosure), so that the enclosure lies close to a wall when mounted thereon.

In another embodiment, the enclosure has a number of air exhausts in the rear sidewall, each having a louver for allowing air to escape while minimizing the possible entry of environmental contaminants.

In another embodiment, a wall mounting bracket is used to mount the enclosure to a wall. The bracket may include a bracket frame with side flanges. When the enclosure is placed against the bracket, e.g., with the rear sidewall facing a wall to which the bracket is connected, the side flanges overlap the left and right sidewalls of the enclosure. The flanges are spaced apart slightly from the enclosure sidewalls to provide gaps through which exhausted air passes. In other words, air is exhausted through the exhausts in the rear sidewall, through the space between the enclosure, bracket, and wall, and out through the gaps towards the front of the enclosure.

In another embodiment, the enclosure includes a door for accessing the enclosure interior. Additionally, a support chassis is pivotally connected to the enclosure. The chassis is used to hold or support electronic components. In other words, various electronic devices, modules, or other components may be attached to the chassis. The chassis is laterally pivotally moveable between retracted and deployed positions. In the retracted position, the chassis lies within the enclosure interior; here, the door may be shut to secure the chassis and seal off the interior. In the deployed position (with the door open), the chassis lies rotated out of the enclosure interior. In this position, a user may more easily access electronic components supported by the chassis, allowing for the enclosure to have a shallower depth for placement in locations with limited space. The chassis has a pivot axis on the same side as the door for cooperative movement with the door.

### BRIEF DESCRIPTION OF THE DRAWINGS

The present invention will be better understood from reading the following description of non-limiting embodiments, with reference to the attached drawings, wherein below:

FIG. 1 is a perspective view of an articulated electronics enclosure system according to an embodiment of the present invention;

FIG. 2 is a front side elevation view of the enclosure system;

FIG. 3 is a rear side elevation view of the enclosure system;

FIG. 4 is a top plan view of the enclosure system;

FIG. 5 is a side elevation view of the enclosure system with a door portion thereof in an open position;

FIG. 6 is a perspective view of the enclosure system showing an interior chassis in a deployed/rotated position;

FIG. 7 is a schematic front side elevation view, partly in cutaway, of the enclosure system showing coolant air flow through the enclosure;

FIG. 8 is a top plan view of the enclosure system, partly in cutaway, showing air flow through the enclosure;

FIGS. 9A and 9B are detailed schematic views of air intake baffles;

FIG. 10A is a schematic top plan view showing the operation of an enclosure according to the prior art;

FIG. 10B is a schematic top plan view showing the operation of an embodiment of the enclosure of the present invention;

FIG. 11A is a perspective view of an alternative embodiment of a base portion of the enclosure;

FIG. 11B is a side elevation view of the base in FIG. 11A, shown in partial cutaway; and

FIG. 11C is a detail view of the base as shown in FIG. 11B.

### DETAILED DESCRIPTION

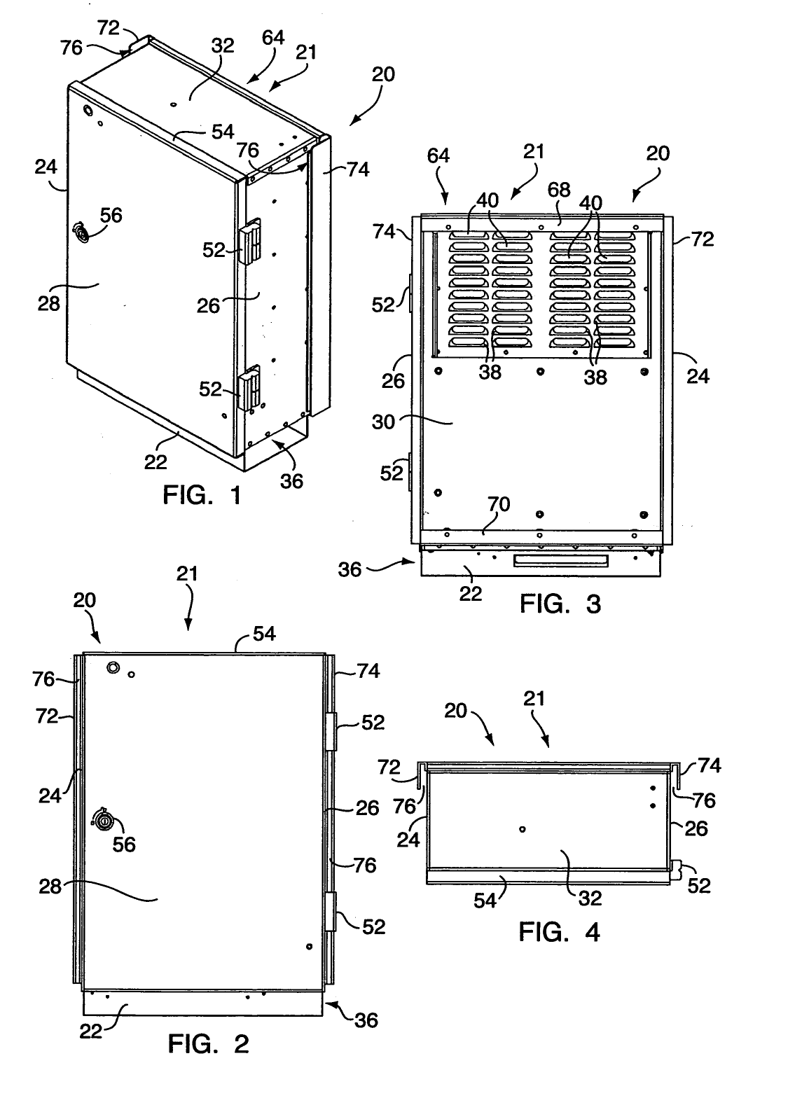

With reference to FIGS. 1-9B and 10B, an embodiment of the present invention relates to an articulated enclosure system 20 for housing electronic components. The system 20 includes an exterior frame or enclosure 21 having a base 22, left and right sidewalls 24, 26, front and rear sidewalls 28, 30, and a top sidewall 32, all of which define an interior 34 of the enclosure. One or more air intakes 36, e.g., passageways through which air can flow, extend from the base 22 (at the exterior bottom of the enclosure 21) into the enclosure interior 34. The rear sidewall 30 has one or more air exhaust ports 38 extending therethrough. The exhaust ports 38 are each provided with a baffle such as a louver 40 attached to the rear sidewall 30. The air intake 36 is also provided with a baffle 42. The baffles 40, 42 allow air to pass while limiting the ingress of environmental contaminants such as dust, debris, and sprayed liquid. In operation, air is drawn into the enclosure through the air intake 36 by way of a standard fan unit 44, for thermal management (e.g., cooling) purposes. The air circulates through the interior 34, and is exhausted to the rear of the enclosure through the exhaust ports 38. This air flow pattern or pathway substantially reduces the likelihood of liquid contaminants entering the enclosure.

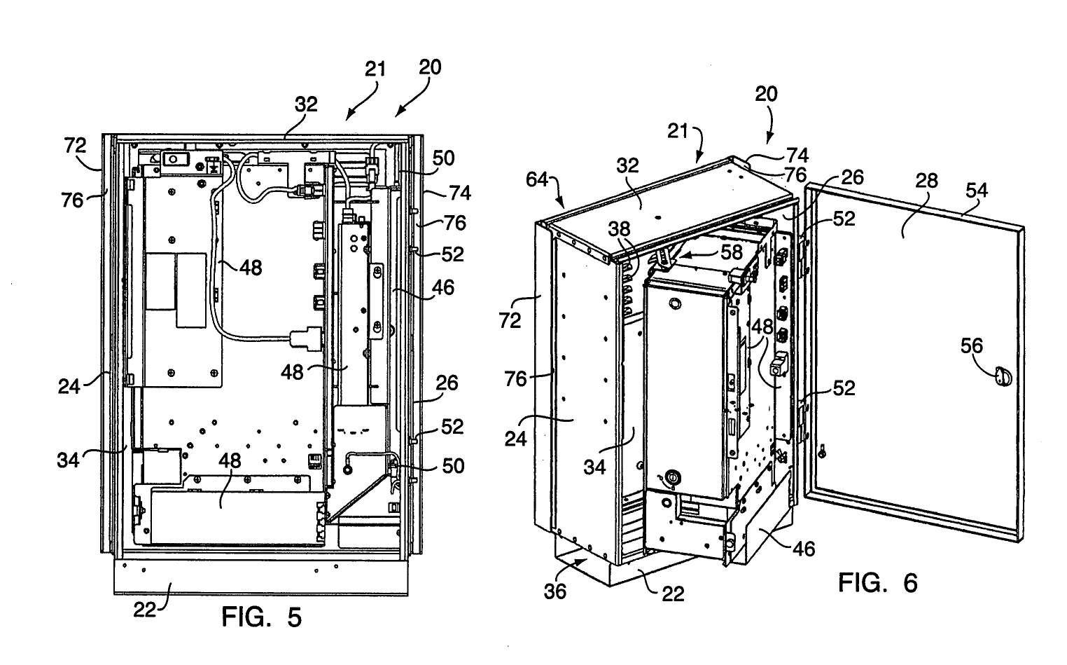

The enclosure 21 also includes an interior support frame or chassis 46 for holding electronic components 48, e.g., computer or telecommunication cards or boards, electronic modules or other devices, or the like. The enclosure system 20 is articulated in nature, meaning that the chassis 46 is laterally pivotally attached to the enclosure 21 by way of hinges or other pivot points 50. Thus, the chassis 46 can be laterally rotated out of the front of the enclosure 21 from a retracted position as shown in FIG. 5 to a deployed position as shown in FIGS. 6 and 10B. In the deployed position, it is easier for a user to access the components 48 supported by the chassis. Additionally, in situations where the electronic components 48 have set, pre-established dimensions independent of the dimensions of the enclosure 21, the chassis 46 enables the components 48 to be oriented laterally (e.g., parallel to the rear sidewall) instead of perpendicularly. (Compare FIGS. 10A and 10B.) This enables the enclosure 21 to have a lower profile, e.g., shallower depth, than conventional enclosures.

Referring back to FIGS. 1-4, the enclosure 21 is generally rectangular in overall shape. For use in certain applications, the enclosure 21 may be substantially wider than it is deep, by which it is meant that a depth of the enclosure will be no more than about one-half of the width of the enclosure. (In other words, the width of the front or rear sidewall 28, 30 may be at least about twice the width of the left or right sidewall 24, 26.) This facilitates placement of the enclosure 21 in locations without much depth and/or where space is at a premium, such as in closets and utility cabinets. Under the relative dimensions as shown in the drawings, it has been found that the enclosure may have a depth D1 (see FIG. 10B) of less than about 250 mm (e.g., 250±1 mm), and as little as about 203 mm, when configured for use in holding standard telecommunications junction/distribution plug-in circuit packs. Such circuit packs are those typically having a depth of at least 260 mm, e.g., a card portion of the circuit pack is typically at least 220 mm deep, with at least 40 mm of additional clearance for connections on the front of the card. This is compared to a typical depth D2 (see FIG. 10A) of at least 300 mm for a standard enclosure for holding such electronic devices, e.g., at least 260 for the circuit pack plus at least an additional 40 mm, and typically more, for the card cage portion of the chassis and enclosure.

The front sidewall 28 of the enclosure 21 is configured for use as a door to access the interior 34. As such, the front sidewall 28 is attached to the right sidewall 26 by way of hinges 52. The front sidewall 28 will typically have a peripheral, rear-facing flange 54 for blocking or sealing the seam between the door and other sidewalls when the door is closed. A key lock 56 may be attached to the front sidewall 28 for locking the door to prevent unauthorized access to the interior 34.

The chassis 46 provides a support frame for attaching and holding the electronic components/devices 48. The chassis 46 maintains the components 48 in a fixed, spaced apart manner for thermal management purposes and to facilitate the orderly and regular placement of cables, jumpers, patches, or the like. The chassis may also provide a support for intermediate cable terminations, connectors, ports, or the like. For example, such a port may be used to removably interconnect an electrical component in the enclosure to an external feed or cable, enabling the external feed to be disconnected without having to access the component. The chassis may be configured in a number of different ways for holding electronic components of different types.

In combination with the electronic components 48 supported thereby, the chassis 46 is dimensioned to fit inside the enclosure interior 34, as shown in FIG. 5. Typically, the chassis will occupy substantially all of the interior space 34, for minimizing the external dimensions of the enclosure 21. (In other words, it will typically be the case that the enclosure 21 need not be substantially larger than the chassis.) As noted above, the chassis 46 is laterally pivotally connected to the enclosure 21 by way of the hinges or other pivots 50. In this manner, with the front sidewall 28 in an open position, the chassis 46 may be swung or rotated out of the front of the enclosure along a longitudinal pivot axis defined by the pivots 50 and positioned along one lateral/side edge of the chassis. Thus, when retracted the chassis lies within the interior 34 as shown in FIG. 5. When rotated out of the interior, the chassis lies deployed as shown in FIGS. 6 and 10B. Whereas the removal and insertion of certain standard-sized electronic devices would normally require the enclosure to have a corresponding depth, as indicated by the prior art enclosure shown in FIG. 10A, the pivoting chassis 46 allows for such devices be similarly securely enclosed but in a much shallower space. Also, since the chassis 46 can be pivoted outwards, it is easier for a user to access the electronic components generally.

As indicated in the drawings, the pivot axis of the chassis 46 is on the same side of the enclosure 21 as the front sidewall (door) 28, for cooperative movement with the door. In other words, the door and chassis are positioned to open in the same direction.

To support the chassis 46 during movement between its retracted and deployed positions, one or more standard guide assemblies 58 may be attached to the enclosure 21 and chassis 46. As shown in FIG. 6, such a guide assembly may include a slide bracket pivotally connected to the enclosure 21 and a bolt-like pin attached to the chassis 46 that slides along a track in the bracket.

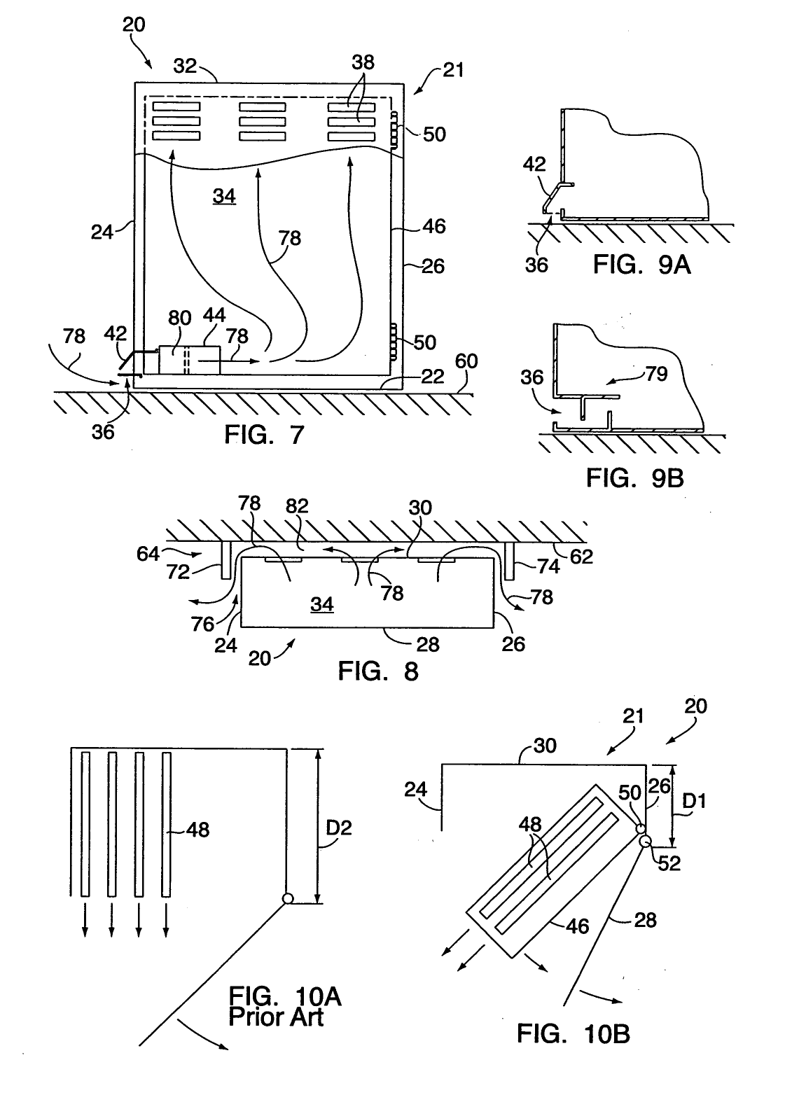

For deployment or placement of the enclosure 21, the enclosure 21 is typically placed with the base 22 against a floor surface 60 and with the rear sidewall 30 facing a wall 62 (see FIGS. 7 and 8). For support purposes and/or to prevent removal of the enclosure, the enclosure 21 may be mounted to the wall 62. For wall mounting, and for further limiting the possibility of contamination (especially from sprayed water), the system 20 includes a wall mounting bracket 64. The wall mounting bracket 64, as best seen in FIG. 3, is a rectangular frame having a top cross-member 68, a bottom cross-member 70, and forwards-facing left and right flanges 72, 74. (The top and bottom cross-members 68, 70 may also be forwards facing flanges.) The bracket 64 also includes various mounting apertures or the like for connecting the bracket to the wall 62. The wall mounting bracket 64 is generally complementary in shape to the rear sidewall 30, enabling the rear of the enclosure to be placed within the confines of the bracket 64 and flanges 68, 70, 72, 74. The enclosure 21 is attached to the bracket 64 in a standard manner through the interior 34, using fasteners or the like. For allowing exhausted coolant air to escape the rear of the enclosure, one or more gaps 76 are provided between the flanges or cross-members 68, 70, 72, 74 and the enclosure 21, depending on the direction in which it is desired to direct the exhausted air. For example, as shown in FIGS. 1, 4, and 8, the bracket 64 and enclosure 21 may be configured for the left and right flanges 72, 74 to be spaced apart slightly from the left and right sidewalls 24, 26 when the enclosure 21 is placed against the bracket 64. In the configuration shown in FIGS. 1, 4, and 8, the top and bottom flanges 68, 70 abut the top sidewall 32 and base 30, respectively, to provide a measure of sealing there between. (As indicated in FIGS. 1 and 3, the base 30 may have a smaller footprint than the sidewalls; in such a case the bottom flange 70 abuts the bottom lip of the rear sidewall 30.)

For cooling the electronic devices 48, the enclosure is provided with an air pathway 78 through which air is directed in a controlled manner. Initially, air (acting as a coolant) is drawn in through the air intake 36 in the base 22. Typically, the air intake 36 will be located toward the bottom and on one side of the base. Optionally, both the left and right sides of the base have such an air intake, with the two intakes forming a common duct or other passageway. The opening of the air intake is restricted or shielded by the baffle 42. The baffle 42 may be a downwards-facing hood or louver externally attached to the enclosure sidewall, as shown in FIGS. 7 and 9A. (The baffle 42 is not shown in FIGS. 1-6.) Alternatively, as shown in FIG. 9B, the baffle may be an internal baffle comprising a number of opposite facing flanges or walls 79 that together define a serpentine path allowing for the flow of air but restricting the passage of liquid and solid contaminants. Other baffle arrangements are possible. Air is drawn in through the air intake 36 by way of the electrically powered fan unit 44 and a standard air filter (not shown). The fan unit 44 may be built into the enclosure 21, or it may be attached to the chassis 46. For the latter, the chassis 46, enclosure 21, and fan 44 are complementarily configured and/or positioned for the fan 44 to draw air in through the air intake 36 when the chassis is in the retracted position. In other words, when the chassis is retracted the air intake and fan duct 80 together form a continuous passageway that is sealed to such an extent as to allow the fan to effectively draw air in through the air intake and out the rear of the fan unit into the interior of the enclosure 34.

Once drawn into the enclosure 21, air passes through the interior 34, around the components 48 (for cooling purposes), and out through the air exhaust ports 38 in the rear sidewall 30. For ensuring that the air is exhausted through the ports 38 (and to minimize the entry of contaminants), the enclosure 21 is generally sealed. By this, it is meant that the enclosure is airtight when the front sidewall 28 is closed, except as to slight variances or gaps between components resulting from manufacturing tolerances and/or to allow for clearance between moving parts, and except for the air intake 36 and exhaust ports 38. Thus, the air intake 36 and exhaust ports 38 provide the primary entrance and exit points for air into and out of the enclosure, respectively. As noted, downwards facing louvers 40 attached to the rear sidewall 30 are positioned over the exhaust ports 38 to restrict the entry of contaminants.

Since air is exhausted through the ports 38 towards the rear of the enclosure 21, a clearance 82 (see FIG. 8) is provided between the rear sidewall 30, the bracket 64, and the wall 62 when the enclosure 21 is in place against the bracket 64. Thus, after exiting the ports 38, exhausted air passes through the clearance 82 along the wall 62 and out through the gaps 76 between the side flanges 72, 74 of the bracket 64 and the sidewalls 24, 26 of the enclosure 21. This directs the exhausted air towards the front of the enclosure.

As should be appreciated, the air pathway 78 of the present invention comprises drawing air in from the bottom of the enclosure and exhausting the air towards the wall at the rear of the enclosure. This pathway/route has been found to facilitate compliance of the enclosure with certain environmental and/or product testing standards. For example, an enclosure built according to the present disclosure was able to meet IEC (International Electrotechnical Commission) IP44 standards, which includes a water spray test that is generally difficult to pass when intaking and exhausting air. Under the IP44 standards, this means that the enclosure protects against the entry of solid foreign objects of 1 mm diameter and greater, and that the enclosure protects against splashing or sprayed water at least to the extent as specified in the standard. The mounting bracket 64 (e.g., bracket flanges 68, 70, 72, 74) helps shield the rear of the enclosure when the enclosure is wall mounted. The baffles 42 and louvers 40 also help in preventing the entry of sprayed water or other liquid into the enclosure interior 34.

The enclosure 21 and chassis 46 may be made of one or more durable materials such as metal, polymer, composites, or the like.

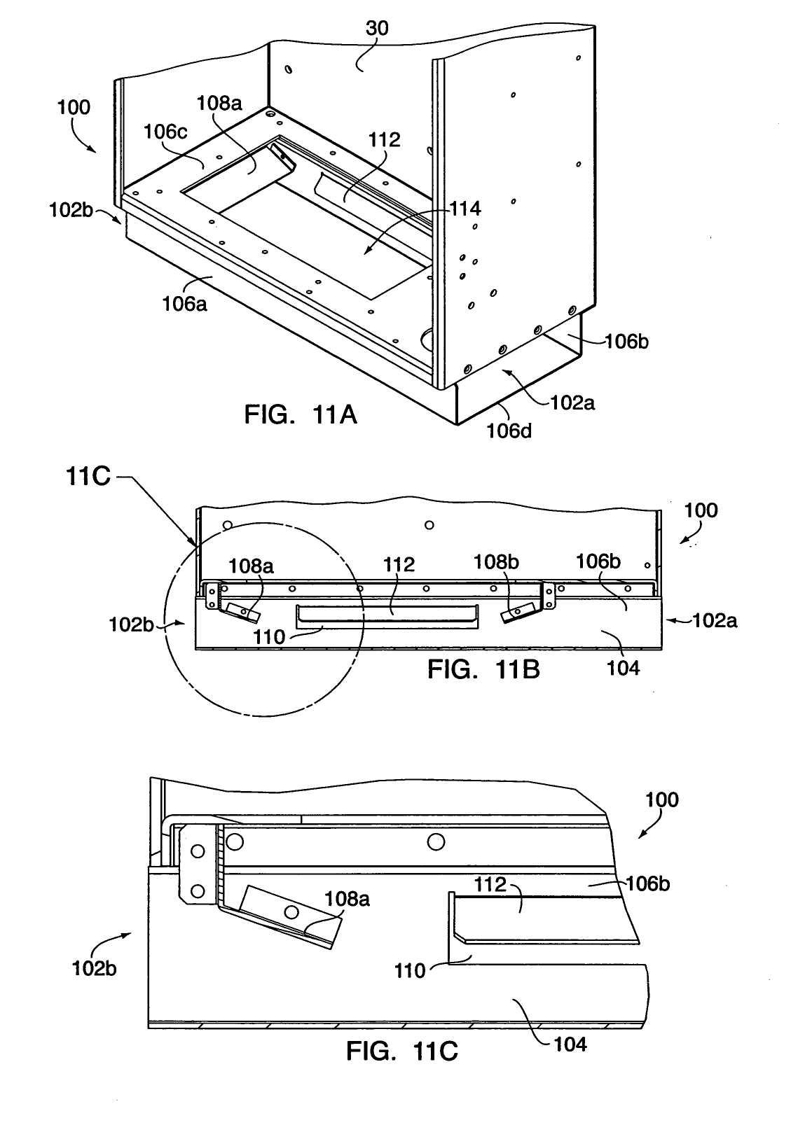

FIGS. 11A-11C show an alternative embodiment of a base 100 for the enclosure system 20. The base 100 is generally similar to the base 22 described above, but includes two air intakes 102a, 102b at either end of a common intake duct 104 extending along a longitudinal length of the base 100. The duct 104 is defined by interconnected front, rear, top, and bottom members 106a-106d, respectively. Inwardly angled inner baffles 108a, 108b project down into the duct from the top of the base. The baffles 108a, 108b also extend laterally across the width of the duct as shown in FIG. 11A. The base 100 is also optionally provided with an additional intake slot 110 in the rear member 106b of the base, e.g., facing in the same direction as the rear sidewall 30. An inwardly directed baffle 112 for shielding the rear intake slot 110 is attached to or integral with the rear portion 106b of the base 100. Also shown in FIGS. 11A-11C is an upper intake opening 114 in the base 100 over which a fan/filter unit could be positioned for drawing air in through the intakes 102a, 102b. Note that the baffles 108a, 108b, 112 may be generally distributed around the periphery of the air opening 114 for shielding the opening 114 in its function as the common intake point for air into the fan/interior.

Since certain changes may be made in the above-described articulated electronics enclosure, without departing from the spirit and scope of the invention herein involved, it is intended that all of the subject matter of the above description or shown in the accompanying drawings shall be interpreted merely as examples illustrating the inventive concept herein and shall not be construed as limiting the invention.

We claim:

1. An enclosure system for housing electronic components comprising:
an enclosure having an interior, a base defining a bottom of the enclosure, and a rear sidewall; and
an air coolant pathway extending from at least one air intake in the base, through the interior, and to at least one air exhaust in the rear sidewall.

2. The system of claim 1 wherein the base and rear sidewall each have at least one baffle attached thereto and associated with the at least one air intake and the at least one air exhaust, respectively, for limiting the entry of contaminants through the intake and exhaust.

3. The system of claim 2 wherein the base has a front, a rear, and left and right sides, said left and right sides of the base being shorter in length than the front and rear of the base, and wherein the at least one air intake is disposed in at least one of the left and right sides of the base.

4. The system of claim 3 wherein the at least one air intake comprises first and second air intakes disposed in the left and right sides of the base, respectively.

5. The system of claim 2 wherein a depth of the enclosure is no more than about one-half a width of the enclosure.

6. The system of claim 2 further comprising a plurality of air exhausts in the rear sidewall, each of said air exhausts having a baffle associated therewith for limiting the entry of contaminants through the exhausts.

7. The system of claim 6 wherein the baffles for the air exhausts are louvers.

8. The system of claim 6 wherein the air exhausts are distributed across a width of the rear sidewall proximate a top of the enclosure.

9. The system of claim 2 further comprising:
a wall mounting bracket complementary in shape to the rear sidewall for mounting the enclosure to a wall, said bracket having at least one flange configured to overlap at least one of said sidewalls of the enclosure when the rear sidewall of the enclosure is brought to bear against the bracket, wherein there is at least one gap between the at least one flange and the at least one of said enclosure sidewalls for the passage of exhausted air.

10. The system of claim 9 wherein the bracket comprises a bracket frame and at least first and second side flanges extending along respective sides of the frame, wherein the side flanges are configured to overlap left and right sidewalls of the enclosure when the rear wall of the enclosure is brought to bear against the bracket.

11. The system of claim 9 wherein the air coolant pathway further extends from the at least one air exhaust, through a space defined between the rear sidewall, bracket, and wall, and out through the at least gap towards a front of the enclosure.

12. The system of claim 9 wherein the enclosure extends no more than about 250 mm away from the wall when mounted thereon by way of the bracket.

13. The system of claim 2 wherein:
a front sidewall of the enclosure comprises a door for accessing the interior, said door having a pivot axis positioned on a selected one of a left and right sidewall of the enclosure; and
the system further comprises a support chassis pivotally connected to the enclosure interior and configured for holding at least one electronic device, wherein the support chassis is laterally pivotal between a retracted position where the chassis is located entirely within the interior and a deployed position where at least a portion of the chassis lies rotated out of the interior for accessing electronic devices attached to the chassis, and wherein the chassis has a pivot axis positioned on said selected one of the left and right enclosure sidewalls for cooperative movement with the door.

14. The system of claim 13 wherein the chassis occupies substantially the entirety of the interior when in the retracted position, and wherein the system further comprises at least one guide assembly attached to the enclosure and chassis for supporting and guiding the chassis during movement between the retracted and deployed positions.

15. An enclosure system for housing electronic components comprising:
an enclosure having a base, a rear sidewall attached to the base, an interior defined at least by the base and rear sidewall, and an air pathway extending from at least one air intake in the base, through the interior, and to at least one air exhaust in the rear sidewall; and
a bracket for mounting the enclosure to a wall, wherein the bracket includes at least one flange cooperative with the enclosure for shielding the rear sidewall when the enclosure is mounted to a wall by way of the bracket.

16. The system of claim 15 further comprising:
at least one first baffle attached to the base and at least one second baffle attached to the rear sidewall, said at least one first baffle and said at least one second baffle being associated with the at least one air intake and the at least one air exhaust, respectively, for limiting the entry of contaminants there through.

17. The system of claim 16 wherein the bracket and enclosure define a space between the rear sidewall and the wall when the enclosure is mounted to the wall by way of the bracket, and wherein there is at least one gap between the at least one flange and the enclosure, said space and at least one gap providing for the passage of exhausted air.

18. The system of claim 16 wherein:
the bracket comprises a bracket frame and at least first and second side flanges extending along respective sides of the frame, wherein the side flanges are configured to overlap left and right sidewalls of the enclosure when the rear wall of the enclosure is brought to bear against the bracket.

19. An enclosure system for electronics comprising:
an enclosure defining an interior and having a door for accessing the interior, said door having a pivot axis positioned on a selected one of a left and a right sidewall of the enclosure; and
a support chassis pivotally connected to the enclosure and configured for holding at least one electronic component, wherein the support chassis is pivotal between a retracted position where the chassis is located entirely within the enclosure interior and a deployed position where at least a portion of the chassis lies rotated out of the enclosure interior for accessing electronic components supported by the chassis, and wherein the chassis has a pivot axis substantially parallel to the door pivot axis and positioned on said selected one of the left and right enclosure sidewalls for cooperative movement with the door.

20. The system of claim 19 wherein:
the enclosure includes a base, a rear sidewall, and a plurality of secondary sidewalls, said sidewalls being attached to the base and defining the interior of the enclosure;
the base has at least one air intake; and
the rear sidewall has at least one air exhaust, said at least one air intake and said at least one air exhaust being in fluid communication by way of the enclosure interior for the passage of the air from the at least one intake, through the interior, and out the at least one exhaust.
